(19) United States
(12) Patent Application Publication
(10) Pub. No.: US 2026/0370196 A1
(43) Pub. Date: Nov. 19, 2026

(54) Signal transmission system and related driver circuit for EMI reduction

(71) Applicant: NOVATEK Microelectronics Corp., Hsin-Chu (TW)

(72) Inventors: Cheng-Chun Wu, New Taipei City (TW); Chia-Wei Wang, Hsinchu City (TW); Yen-Wei Chen, Hsinchu City (TW)

(73) Assignee: NOVATEK Microelectronics Corp., Hsin-Chu (TW)

(21) Appl. No.: 19/206,065

(22) Filed: May 13, 2025

(51) Int. Cl. H03F 3/45

(52) U.S. Cl. CPC H03F 3/45475; H03F 2200/129

(57) ABSTRACT

A signal transmission system includes a first operational amplifier (op-amp) and a second op-amp. The first op-amp has a first power supply terminal and a second power supply terminal. The second op-amp has a first power supply terminal and a second power supply terminal. The first op-amp and the second op-amp are connected through a plurality of transmission lines. The first power supply terminal of the first op-amp and the first power supply terminal of the second op-amp are connected through a first transmission line among the plurality of transmission lines, and the second power supply terminal of the first op-amp and the second power supply terminal of the second op-amp are connected through a second transmission line among the plurality of transmission lines.

### BACKGROUND OF THE INVENTION

### 1. Field of the Invention

The present invention relates to a signal transmission system, and more particularly, to a signal transmission system capable of reducing electromagnetic interference (EMI) and its related driver circuit.

### 2. Description of the Prior Art

Modern display products are developing with the trends of high resolution and fast speed; hence, a display device is usually controlled by multiple display driver integrated circuits (ICs) connected in series, and the number of connected ICs becomes increasing and increasing. These driver ICs should perform display control with a synchronous timing by communicating with each other. Therefore, a transmission interface may be connected between two or more driver ICs on a circuit board, to forward necessary synchronization signals between these driver ICs. Examples of the transmission interface include the serial peripheral interface (SPI) and inter-integrated circuit (I2C) interface, but not limited thereto.

With the high-speed transmissions between the driver ICs, it is important to solve the problem of electromagnetic interference (EMI) energies emitted during signal transmissions on the interface therebetween, especially when the display product is used in a vehicle display system. Note that the vehicle has much sophisticated electronic equipment which is susceptible to interference. Basically, the vehicle electronics have a higher requirement for EMI, so as not to influence the driving safety. In current display products, the EMI problem is usually dealt with by controlling the slew rate of the transmitted signals, or by applying differential signals to suppress the emitted EMI energies. However, the effects of these approaches might not be satisfactory due to process variation or mismatch.

### SUMMARY OF THE INVENTION

It is therefore an objective of the present invention to provide a signal transmission system and related driver circuit(s) with a common power loop to improve the electromagnetic interference (EMI) problem.

An embodiment of the present invention discloses a signal transmission system, which comprises a first operational amplifier (op-amp) and a second op-amp. The first op-amp has a first power supply terminal and a second power supply terminal. The second op-amp has a first power supply terminal and a second power supply terminal. The first op-amp and the second op-amp are connected through a plurality of transmission lines. The first power supply terminal of the first op-amp and the first power supply terminal of the second op-amp are connected through a first transmission line among the plurality of transmission lines, and the second power supply terminal of the first op-amp and the second power supply terminal of the second op-amp are connected through a second transmission line among the plurality of transmission lines.

Another embodiment of the present invention discloses a signal transmission system, which comprises a first driver circuit and a second driver circuit. The first driver circuit comprises a plurality of first op-amps, and the second driver circuit comprises a plurality of second op-amps. The first driver circuit and the second driver circuit are connected through a plurality of signal lines and a plurality of power lines. Each of the plurality of first op-amps is connected to a corresponding second op-amp among the plurality of second op-amps through one of the plurality of signal lines. The plurality of first op-amps are commonly coupled to a first power supply terminal and a second power supply terminal in the first driver circuit, and the plurality of second op-amps are commonly coupled to a third power supply terminal and a fourth power supply terminal in the second driver circuit. The first power supply terminal and the third power supply terminal are connected through a first power line among the plurality of power lines, and the second power supply terminal and the fourth power supply terminal are connected through a second power line among the plurality of power lines.

Another embodiment of the present invention discloses a signal transmission system, which comprises a first driver circuit and a second driver circuit. The first driver circuit comprises a first amplifier circuit and a first power control circuit, where the first power control circuit has a first power source and at least one first power switch. The second driver circuit comprises a second amplifier circuit and a second power control circuit, where the second power control circuit has a second power source and at least one second power switch. The first driver circuit and the second driver circuit are connected through a plurality of transmission lines. The first amplifier circuit and the second amplifier circuit are connected through at least one signal line among the plurality of transmission lines. The first power control circuit and the second power control circuit are connected through a plurality of power lines among the plurality of transmission lines.

Another embodiment of the present invention discloses a first driver circuit, which comprises an op-amp, a first switch and a second switch. The op-amp is coupled to a second driver circuit through a plurality of transmission lines. The first switch is coupled between a first power supply terminal of the op-amp and a first power source. The second switch is coupled between a second power supply terminal of the op-amp and a second power source.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a general signal transmission system.

FIG. 2 is a schematic diagram of another signal transmission system.

FIG. 3 is a schematic diagram of a signal transmission system according to an embodiment of the present invention.

FIG. 4 is a schematic diagram of a signal transmission system according to an embodiment of the present invention.

FIG. 5 is a schematic diagram of another signal transmission system according to an embodiment of the present invention.

FIG. 6 is a schematic diagram of a signal transmission system in which the driver circuits are connected through multiple signal lines and power lines.

### DETAILED DESCRIPTION

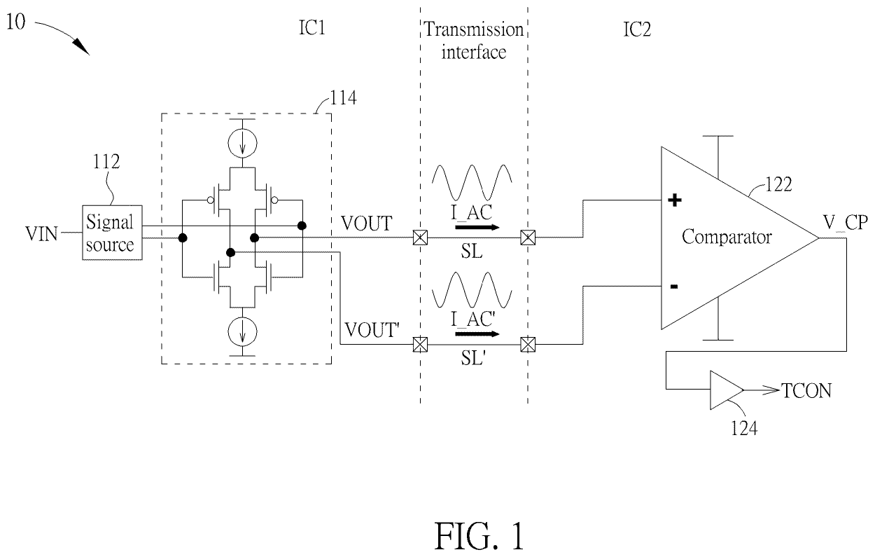

FIG. 1 is a schematic diagram of a general signal transmission system 10. The signal transmission system 10 includes two driver circuits IC1 and IC2, which are connected through a transmission interface. The transmission interface has two signal lines SL and SL′.

In detail, the driver circuit IC1 may transmit differential output signals VOUT and VOUT′ to the driver circuit IC2 through the signal lines SL and SL′. In other words, the driver circuit IC1 may be operated as a transmitter and the driver circuit IC2 may be operated as a receiver in the signal transmission system 10. Therefore, the driver circuit IC1, as a transmitter, includes a signal source 112 and an output driver 114. The signal source 112 is configured to generate and/or forward a source signal VIN to be output to the driver circuit IC2. The output driver 114 is configured to drive the loads on the transmission interface to output the differential output signals VOUT and VOUT′. Since the output driver 114 is requested to output the differential output signals VOUT and VOUT′, it may have a differential output structure, to convert the source signal VIN into differential output signals VOUT and VOUT′ to be output to the driver circuit IC2.

In addition, the driver circuit IC2, as a receiver, includes a comparator 122 and a buffer 124. The comparator 122 may receive the differential output signals VOUT and VOUT′ from the driver circuit IC1 and compare the output signal VOUT with the output signal VOUT′ to generate a comparison result V_CP. The comparison result V_CP may then be sent to a back-end digital circuit through the buffer 124. The buffer 124 may amplify the signal of the comparison result V_CP and output the signal value to a digital processing circuit of the driver circuit IC2, such as a timing controller TCON.

In the transmission interface, it is preferable to deploy the signal lines SL and SL′ to be close to each other, so that the electromagnetic interference (EMI) energies generated by the differential output signals VOUT and VOUT′ may be canceled. In detail, the differential output signals VOUT and VOUT′ may be accompanied by alternating-current (AC) currents I_AC and I_AC′ flowing through the signal lines SL and SL′, respectively, as shown in FIG. 1. The AC currents I_AC and I_AC′ may have equal magnitude and opposite directions. Therefore, if there is no process variation or mismatch, the EMI energies emitted by an AC current (e.g., I_AC′) may be canceled by the EMI energies emitted by another AC current (e.g., I_AC), thereby improving the EMI problem.

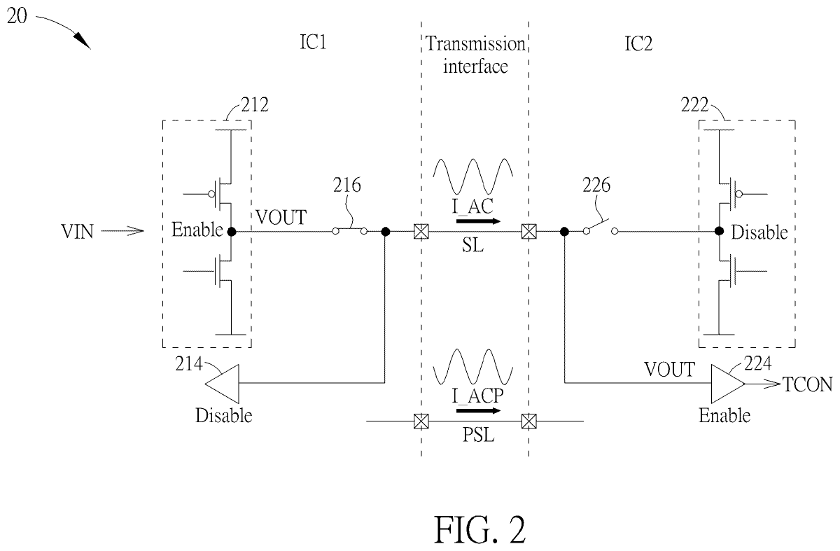

FIG. 2 is a schematic diagram of another signal transmission system 20. The signal transmission system 20 also includes two driver circuits IC1 and IC2 connected with each other through a transmission interface. In this example, the driver circuits IC1 and IC2 have both signal output and signal input functions. More specifically, each of the driver circuits IC1 and IC2 may be configured to be operated in an output enable (OE) mode or an input enable (IE) mode. In the OE mode, the driver circuit IC1 or IC2 may be operated as a transmitter to output signals; and in the IE mode, the driver circuit IC1 or IC2 may be operated as a receiver to receive signals. In another perspective, in a first transmission mode, the driver circuit IC1 may be operated as a transmitter and the driver circuit IC2 may be operated as a receiver; and in a second transmission mode, the driver circuit IC1 may be operated as a receiver and the driver circuit IC2 may be operated as a transmitter.

In such a situation, the signal transmission system 20 may realize bidirectional transmissions, where the driver circuits IC1 and IC2 may have a similar circuit structure to realize the signal output and signal input functions. In detail, the driver circuit IC1 includes a push-pull driver 212, a buffer 214 and a switch 216. The push-pull driver 212, which is enabled in the OE mode, may convert a source signal VIN into an output signal VOUT and output the output signal VOUT to the driver circuit IC2. The buffer 214, which is enabled in the IE mode, may receive a signal from the driver circuit IC2 and forward the signal to the back-end digital processing circuit. The switch 216 may be turned on or off to determine whether to enable the signal output function based on whether the driver circuit IC1 is in the OE mode or the IE mode.

On the other side of the transmission interface, the driver circuit IC2 includes a push-pull driver 222, a buffer 224 and a switch 226. The operations of the push-pull driver 222, the buffer 224 and the switch 226 are identical to those of the push-pull driver 212, the buffer 214 and the switch 216, respectively, and will not be narrated herein.

As shown in FIG. 2, the driver circuit IC1 may be operated in the OE mode and the driver circuit IC2 may be operated in the IE mode. Therefore, in the driver circuit IC1, the switch 216 is turned on, and the push-pull driver 212 outputs the output signal VOUT to the driver circuit IC2, where the output signal VOUT is accompanied by an AC current I_AC. The output signal VOUT with the AC current I_AC is forwarded through the signal line SL of the transmission interface, and then sent to the driver circuit IC2. In the driver circuit IC2, the switch 226 is turned off and the push-pull driver 222 may be disabled. The buffer 224 is enabled to receive the output signal VOUT and forward the output signal VOUT to the back-end digital processing circuit, such as a timing controller TCON.

In order to cancel the EMI energies emitted by the AC current I_AC, a pseudo current I_ACP may be delivered between the driver circuits IC1 and IC2 through a pseudo signal line PSL. The pseudo current I_ACP may be set to have the same magnitude as the AC current I_AC with different current directions. In other words, the pseudo current I_ACP and the AC current I_AC may satisfy the following equation:

I_AC+I_ACP=0. (1)

Note that the rightward arrows shown in FIG. 2 do not mean that the current must flow rightwards. In fact, a person of ordinary skill in the art would understand that the current actually flowing on the signal line SL or PSL may be rightward or leftward based on the swing of the output signal VOUT. In this example, the rightward current may be considered as a positive current and the leftward current may be considered as a negative current. In other words, the value of I_AC or I_ACP is positive if the corresponding current flows rightwards and the value is negative if the corresponding current flows leftwards. Therefore, Equation (1) is satisfied when the magnitudes of the AC current I_AC and the pseudo current I_ACP are equal and these currents I_AC and I_ACP have different directions. In such a situation, the EMI energies emitted by the AC current I_AC and the EMI energies emitted by the pseudo current I_ACP may be canceled with each other.

Note that the pseudo current I_ACP is usually produced from another signal source and output by another driver. Therefore, the pseudo current I_ACP may be deviated from its ideal value, such that the EMI generated by the AC current I_AC may not be canceled effectively.

As mentioned above, the EMI canceling effect of the examples shown in FIG. 1 and FIG. 2 may not be satisfactory. In addition, as for the signal transmission on a channel, two signal lines are necessary when the differential transmission or pseudo transmission is applied. This significantly increases the circuit costs since the signal lines and pads for transmission should be doubled.

Therefore, the present invention provides a signal transmission system in which the transmitter and receiver use a common power supply to realize the EMI reduction. In various embodiments, the power lines and signal lines in the transmission interface may form a closed loop with the two driver circuits, where the currents may flow through the closed loop so that the EMI energies emitted by the overall currents may be perfectly canceled.

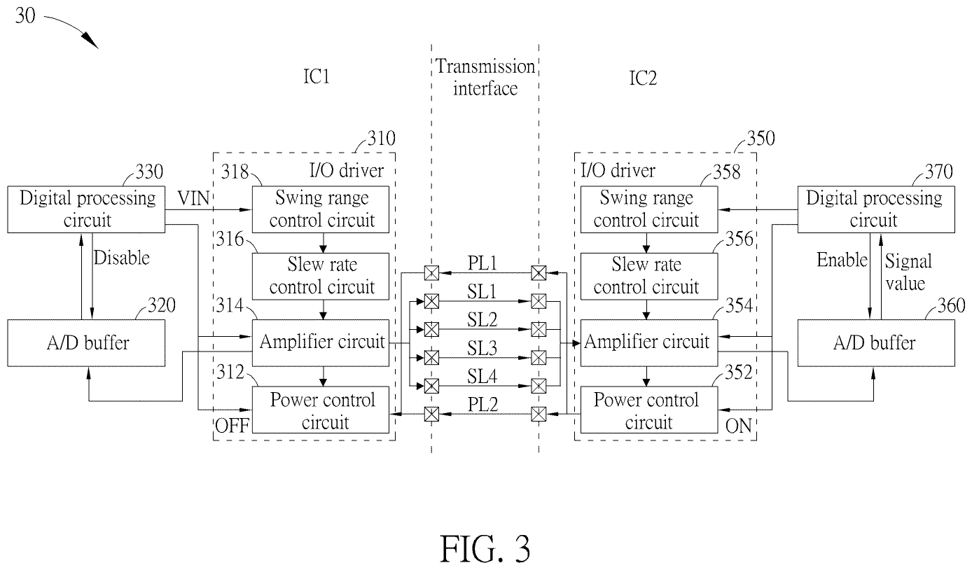

FIG. 3 is a schematic diagram of a signal transmission system 30 according to an embodiment of the present invention. The signal transmission system 30 includes two driver circuits IC1 and IC2. The driver circuits IC1 and IC2 are connected through a transmission interface with multiple transmission lines, which include several power lines PL1 and PL2 and several signal lines SL1-SL4. In one or several embodiments, each of the driver circuits IC1 and IC2 may be implemented as a driver integrated circuit (IC) included in a chip. Therefore, the transmission interface may be implemented on a circuit board to connect the driver circuits IC1 and IC2, where the transmission interface may be, but not limited to, the SPI or I2C interface. For instance, the circuit board may be a printed circuit board (PCB) or a flexible printed circuit (FPC) board, but not limited thereto. Therefore, each driver circuit IC1 and IC2 may be connected to the transmission interface through multiple signal pads.

In one or several embodiments, the signal transmission system 30 may be implemented in a display system having multiple display driver ICs (DDICs) for controlling different parts of the display panel, respectively. Therefore, each driver circuit IC1 and IC2 may be a DDIC, which communicate with each other to send display control signals. The display control signals make the DDICs control the display panel synchronously, allowing the display panel to display images normally. In an exemplary embodiment, the display control signal delivered between the driver circuits IC1 and IC2 may be a synchronization signal, which is used to synchronize the display operations of the driver circuits IC1 and IC2.

Similarly, in this embodiment, the signal transmission system 30 may realize bidirectional transmissions. As shown in FIG. 3, the driver circuits IC1 and IC2 may have a similar circuit structure to realize the signal output and signal input functions of the bidirectional transmissions. In detail, the driver circuit IC1 includes an input/output (I/O) driver 310, an analog-to-digital (A/D) buffer 320 and a digital processing circuit 330; and the driver circuit IC2 includes an I/O driver 350, an A/D buffer 360 and a digital processing circuit 370. Similarly, each driver circuit IC1 and IC2 may be operated in an OE mode or an IE mode. For example, as shown in FIG. 3, the driver circuit IC1 is operated in the OE mode and the driver circuit IC2 is operated in the IE mode to realize the rightward signal transmission. In another embodiment, it is possible to set the driver circuit IC1 to be in the IE mode and set the driver circuit IC2 to be in the OE mode to realize the leftward signal transmission.

In the driver circuit IC1, the digital processing circuit 330 may control the overall operations of the driver circuit IC1. For example, the digital processing circuit 330 may control each block of the driver circuit IC1 to be enabled or disabled or operated appropriately to realize the operations in the OE mode or the IE mode. In an embodiment, if the signal transmission system 30 is used for controlling a display panel, the driver circuit IC1 would be a DDIC; hence, the digital processing circuit 330 may be a timing controller, which is responsible for controlling the display operations of the display panel, and accordingly controlling the signal transmissions of the driver circuit IC1 to realize the display control.

The I/O driver 310 may include a power control circuit 312 and an amplifier circuit 314. As shown in FIG. 3, the power control circuit 312 may be connected to the power control circuit 352 of the I/O driver 350 through the power lines PL1 and PL2, and the amplifier circuit 314 may be connected to the amplifier circuit 354 of the I/O driver 350 through the signal lines SL1-SL4. In the I/O driver 310, the power control circuit 312 may include a power source and one or more power switches, which are turned on or off appropriately to control the power source to supply power to the driver circuits IC1 and/or IC2. In several embodiments, the power source of the power control circuit 312 may supply power to the driver circuit IC2 through the power lines PL1 and/or PL2. In some embodiments, some power switches of the power control circuit 312 may be turned off, so that the driver circuit IC1 may receive power from the driver circuit IC2 (e.g., the power control circuit 352) through the power lines PL1 and/or PL2. With appropriate power arrangement, a closed current loop may be formed between the driver circuits IC1 and IC2 through the power lines PL1 and PL2 and the signal lines SL1-SL4, where the EMI energies of the signal currents (e.g., AC currents) flowing through the signal lines SL1-SL4 and the power currents (e.g., DC currents) flowing through the power lines PL1 and PL2 may be perfectly canceled.

The amplifier circuit 314 may include one or more operational amplifiers (op-amps). As shown in FIG. 3, there are 4 I/O channels corresponding to the 4 signal lines SL1-SL4, respectively; hence, there may be 4 op-amps included in the amplifier circuit 314. If the driver circuit IC1 is in the OE mode, each op-amp may be operated as a unity gain buffer, which may include a push-pull driver used to output signals to the corresponding signal line SL1-SL4. If the driver circuit IC2 is in the IE mode, each op-amp may be operated as a comparator, which may receive signals from the corresponding signal line SL1-SL4, and compare each signal with a reference signal to generate a comparison result, which is then sent to the digital processing circuit 330 (through the A/D buffer 320) for subsequent analysis and processing.

In several embodiments, the I/O driver 310 may further include a slew rate control circuit 316 and a swing range control circuit 318. The slew rate control circuit 316 may control the slew rate of the signals output by the driver circuit IC1, thereby suppressing the EMI energies emitted by the output signals through slew rate control. The swing range control circuit 318 may control the swing range of the signals output by the driver circuit IC1, thereby suppressing the EMI energies emitted by the output signals through swing range control. Note that the present invention mainly applies a power arrangement scheme to mitigate the EMI problem of the signal transmission system 30. The slew rate control circuit 316 and the swing range e control circuit 318 may provide additional EMI suppressing to enhance the performance of EMI reduction. In another embodiment, the slew rate control circuit 316 and/or the swing range control circuit 318 may be omitted, and the EMI reduction effect may still be achieved by using the power arrangement scheme with the closed loop deployment.

The A/D buffer 320 may be enabled when the driver circuit IC1 is in the IE mode and disabled when the driver circuit IC1 is in the OE mode. When the A/D buffer 320 is enabled, it may forward the signal values received from the I/O driver 310 to the digital processing circuit 330 by performing an analog-to-digital conversion.

On the other side of the transmission interface in the signal transmission system 30, the implementations and operations of the I/O driver 350 (including a power control circuit 352, an amplifier circuit 354, a slew rate control circuit 356 (optional) and a swing range control circuit 358 (optional)), the A/D buffer 360, and the digital processing circuit 370 in the driver circuit IC2 are similar to those of the corresponding circuit blocks in the driver circuit IC1, and will not be repeated herein.

The signal transmission system 30 may be operated in different transmission modes to realize the bidirectional transmissions. In a first transmission mode, the driver circuit IC1 may be in the OE mode and the driver circuit IC2 may be in the IE mode; hence, the power switch(s) of the power control circuit 312 may be turned off while the power switch(s) of the power control circuit 352 may be turned on, to control the amplifier circuits 314 and 354 to receive power from the power source of the power control circuit 352 in the driver circuit IC2. In such a situation, the amplifier circuit 314 may receive power from the power source of the power control circuit 352 through the power lines PL1 and/or PL2. In a second transmission mode, the driver circuit IC1 may be in the IE mode and the driver circuit IC2 may be in the OE mode; hence, the power switch(s) of the power control circuit 312 may be turned on while the power switch(s) of the power control circuit 352 may be turned off, to control the amplifier circuits 314 and 354 to receive power from the power source of the power control circuit 312 in the driver circuit IC1. In such a situation, the amplifier circuit 354 may receive power from the power source of the power control circuit 312 through the power lines PL1 and/or PL2. As a result, the amplifier circuits 314 and 354 receive a common power supply from one of the driver circuits IC1 and IC2, thereby achieving the common power loop to ease the EMI problem.

In the embodiment shown in FIG. 3, the driver circuit IC1 is operated in the OE mode and the driver circuit IC2 is operated in the IE mode. In the driver circuit IC1, the digital processing circuit 330 may control the op-amps of the amplifier circuit 314 to be implemented as unity gain buffers and turn off the power switches of the power control circuit 312 accordingly, and also control the A/D buffer 320 to be disabled. The digital processing circuit 330 may also provide source signals VIN to the I/O driver 310. The source signals VIN may be optionally processed by the swing range control circuit 318 and the slew rate control circuit 316, and then be sent to the amplifier circuit 314. Based on the source signals VIN, the amplifier circuit 314 may send the corresponding output signals to the signal lines SL1-SL4, which forward the output signals to the driver circuit IC2.

In the driver circuit IC2 operated in the IE mode, the digital processing circuit 370 may control the op-amps of the amplifier circuit 354 to be implemented as comparators and turn on the power switches of the power control circuit 352 accordingly, and also control the A/D buffer 360 to be enabled. When receiving the output signals from the signal lines SL1-SL4, the op-amps of the amplifier circuit 354 may compare each output signal with a reference signal to determine the value of the signal, and send the comparison result to the A/D buffer 360. The A/D buffer 360 then forwards the signal value to the digital processing circuit 370. With the turn-on power switches, the power source of the power control circuit 352 supplies power to the amplifier circuit 354, and also to the amplifier circuit 314 in the driver circuit IC1 through the power lines PL1 and PL2.

In another transmission mode, the driver circuit IC1 may be operated in the IE mode and the driver circuit IC2 may be operated in the OE mode. The op-amps and other related components of the driver circuits IC1 and IC2 may be operated accordingly to realize the signal transmissions. The operations could be inferred by those skilled in the art, and will not be narrated herein.

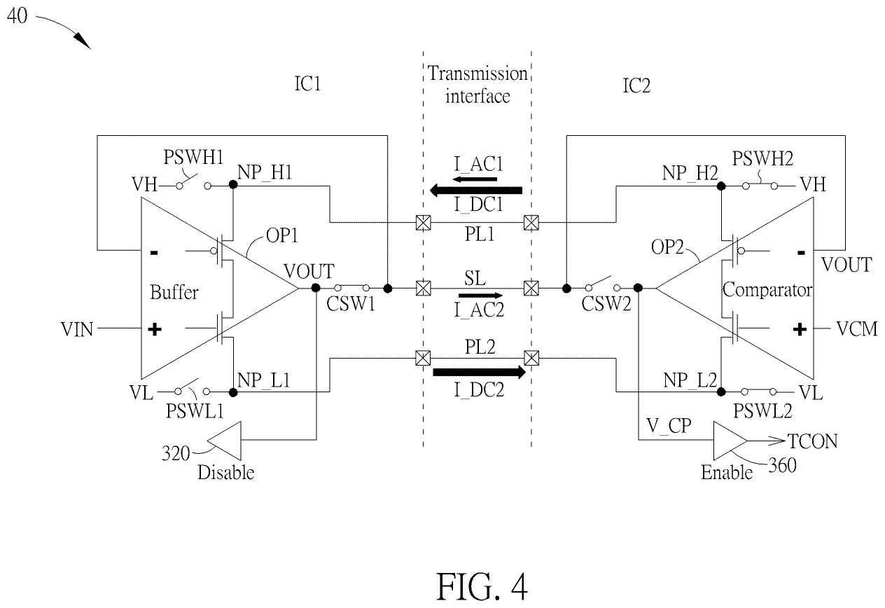

FIG. 4 is a schematic diagram of a signal transmission system 40 according to an embodiment of the present invention, which may be a detailed implementation of the signal transmission system 30 shown in FIG. 3. In FIG. 4, there are an op-amp OP1 in the driver circuit IC1 at the transmitter side and an op-amp OP2 in the driver circuit IC2 at the receiver side. The op-amps OP1 and OP2 may be implemented in one of the multiple channels in the I/O drivers 310 and 350, and may be coupled through a signal line SL for delivering an output signal VOUT. The signal line SL may be one of the signal lines SL1-SL4 shown in FIG. 3.

In addition, the op-amps OP1 and OP2 are connected through two power lines PL1 and PL2 to realize the common power loop. In detail, the op-amp OP1 may have a high-side power supply terminal NP H1 and a low-side power supply terminal NP_L1, and the op-amp OP2 may have a high-side power supply terminal NP H2 and a low-side power supply terminal NP L2. The high-side power supply terminal NP H1 of the op-amp OP1 and the high-side power supply terminal NP H2 of the op-amp OP2 are connected through the power line PL1. The low-side power supply terminal NP_L1 of the op-amp OP1 and the low-side power supply terminal NP L2 of the op-amp OP2 are connected through the power line PL2. The op-amps OP1 and OP2 may receive a first power supply voltage VH through the high-side power supply terminals NP H1 and NP H2, respectively, where the first power supply voltage VH may be a positive voltage. The op-amps OP1 and OP2 may also receive a second power supply voltage VL through the low-side power supply terminals NP_L1 and NP L2, respectively, where the second power supply voltage VL may be a ground voltage or a negative voltage.

FIG. 4 also shows a simplified structure of the op-amps OP1 and OP2, which include a push-pull driver that may be configured in an appropriate manner to output signals in the OE mode and may be disabled in the IE mode. In order to realize the switching between the OE mode and the IE mode, a control switch CSW1 is coupled between the output terminal of the op-amp OP1 and the signal line SL, and a control switch CSW2 is coupled between the output terminal of the op-amp OP2 and the signal line SL. In such a situation, the control switch CSW1 may be connected to the control switch CSW2 through the signal line SL. The left side of the signal line SL is further coupled to the negative input terminal of the op-amp OP1, and the right side of the signal line SL is further coupled to the negative input terminal of the op-amp OP2.

Therefore, the control switches CSW1 and CSW2 may be controlled appropriately to realize the transmission mode of the driver circuits IC1 and IC2. If the driver circuit IC1 or IC2 is in the OE mode, the corresponding control switch CSW1 or CSW2 may be turned on; and if the driver circuit IC1 or IC2 is in the IE mode, the corresponding control switch CSW1 or CSW2 may be turned off.

In the embodiment shown in FIG. 4, the driver circuit IC1 is in the OE mode and the driver circuit IC2 is in the IE mode, and the driver circuit IC1 is operated as a transmitter and the driver circuit IC2 is operated as a receiver. In such a situation, the control switch CSW1 is turned on, allowing the op-amp OP1 to be operated as a unity gain buffer to output the output signal VOUT to the signal line SL. The op-amp OP1 may receive a source signal VIN, and convert the source signal VIN into the output signal VOUT to be output. The control switch CSW2 is turned off, so that the output signal VOUT from the signal line SL may be sent to the negative input terminal of the op-amp OP2. The op-amp OP2 may also receive a reference signal VCM through its positive input terminal. Therefore, the op-amp OP2 may compare the output signal VOUT with the reference signal VCM to generate a comparison result V_CP indicating the signal value, which is sent to the back-end digital processing circuit through the A/D buffer 360. The digital processing circuit may include a timing controller TCON, but not limited thereto.

In addition, several power switches are included in the driver circuits IC1 and IC2 and coupled to the op-amps OP1 and OP2 to realize the power control circuit 312 and 352 for common power supply. In detail, the driver circuit IC1 includes two power switches PSWH1 and PSWL1, where the power switch PSWH1 is coupled between the high-side power supply terminal NP H1 of the op-amp OP1 and a power source of the driver circuit IC1 for supplying the first power supply voltage VH, and the power switch PSWL1 is coupled between the low-side power supply terminal NP_L1 of the op-amp OP1 and another power source of the driver circuit IC1 for supplying the second power supply voltage VL. Similarly, the driver circuit IC2 includes two power switches PSWH2 and PSWL2, where the power switch PSWH2 is coupled between the power supply terminal NP H2 of the op-amp OP2 and a power source of the driver circuit IC2 for supplying the first power supply voltage VH, and the power switch PSWL2 is coupled between the power supply terminal NP L2 of the op-amp OP2 and another power source of the driver circuit IC2 for supplying the second power supply voltage VL.

In one or several embodiments, when a driver circuit is in the OE mode, the power switch in this driver circuit may be turned off; when a driver circuit is in the IE mode, the power switch in this driver circuit may be turned on. In the embodiment shown in FIG. 4, the driver circuit IC1 is in the OE mode and the driver circuit IC2 is in the IE mode. In such a situation, the power switches PSWH1 and PSWL1 of the driver circuit IC1 are turned off, and the power switches PSWH2 and PSWL2 of the driver circuit IC2 are turned on. Therefore, the op-amp OP2 receives the power supply voltages VH and VL from the power sources of the driver circuit IC2. Since the high-side power supply terminals NP H1 and NP H2 of the op-amps OP1 and OP2 are connected through the power line PL1, the op-amp OP1 of the driver circuit IC1 may also receive the first power supply voltage VH from the power source of the driver circuit IC2. Since the low-side power supply terminals NP_L1 and NP L2 of the op-amps OP1 and OP2 are connected through the power line PL2, the op-amp OP1 of the driver circuit IC1 may also receive the second power supply voltage VL from the power source of the driver circuit IC2. As a result, both the op-amps OP1 and OP2 receive power from the same power sources of the driver circuit IC2 at the receiver side.

In this way, the high-side power source of the driver circuit IC2 supplies the first power supply voltage VH to the op-amp OP2 and also to the op-amp OP1 through the power line PL1. With the first power supply voltage VH supplied to the op-amp OP1, a direct-current (DC) current I_DC1 may flow through the power line PL1. In addition, the low-side power source of the driver circuit IC2 supplies the second power supply voltage VL to the op-amp OP2 and also to the op-amp OP1 through the power line PL2. With the second power supply voltage VL supplied to the op-amp OP1, a DC current I_DC2 may flow through the power line PL2.

In addition, the op-amp OP1 transmits the output signal VOUT to the op-amp OP2, and the transmission of the output signal VOUT is accompanied by an AC current I_AC2 flowing through the signal line SL. The AC current I_AC2 may be supplied from the power supply of the op-amp OP1. As mentioned above, the op-amp OP1 receives the power supply voltages VH and VL from the power source of the driver circuit IC2 through the power lines PL1 and PL2. Therefore, the AC current I_AC2 may be supplied from the driver circuit IC2, with an AC current I_AC1 flowing through the power line PL1 or PL2. Note that FIG. 4 shows that the AC current I_AC2 may be a charging current to pull high the level of the output signal VOUT and be supplied through the power line PL1. Sometimes the AC current I_AC2 may be a discharging current to pull low the level of the output signal VOUT, and at this time, the corresponding AC current I_AC1 may flow through the power line PL2.

Since the op-amp OP1 receives power from the driver circuit IC2 through the power lines PL1 and PL2, the DC current I_DC1 flowing through the power line PL1 and the DC current I_DC2 flowing through the power line PL2 may have the same magnitude and different directions. In addition, since the current used for transmitting the output signal VOUT is supplied from the power source of the driver circuit IC2 through the power lines PL1 and/or PL2, the AC current I_AC2 corresponding to the output voltage VOUT flowing through the signal line SL may be exactly equal to the AC current I_AC1 flowing through the power line PL1 or PL2, which means that the AC currents I_AC1 and I_AC2 may have the same magnitude and different directions. Assuming that the rightward current transmission is represented by a positive current and the leftward current transmission is represented by a negative current, these currents forwarded on the transmission interface may satisfy the following equation:

I_AC1+I_DC1+I_AC2+I_DC2=0. (2)

In such a situation, the EMI energies emitted by the rightward currents (e.g., I_AC2 and I_DC2) may be perfectly canceled by the EMI energies emitted by the leftward currents (e.g., I_AC1 and I_DC1).

Note that FIG. 4 shows that the output signal VOUT is in a high level and the AC current I_AC2 is a charging current used to pull high the signal level. In another situation, the output signal VOUT may be in a low level, and the AC current I_AC2 may be a discharging current flowing leftwards and further sinking to the low-side power source of the driver circuit IC2 through the power line PL2. In other words, the AC current I_AC1 may flow through the power line PL2. In such a situation, Equation (2) is still established, and the EMI reduction effect may still be achieved.

With the common power supply of the op-amps OP1 and OP2, the current paths in the transmission interface between the driver circuits IC1 and IC2 may form a closed current loop. More specifically, the op-amps OP1 and OP2, the signal line SL and the power lines PL1 and PL2 may form a closed current loop between the driver circuits IC1 and IC2, where the overall current may flow from the high-side power source of the driver circuit IC2 to the low-side power source of the driver circuit IC2 through the power lines PL1 and PL2 and the op-amp OP1.

In another embodiment, if the op-amp OP1 is in the IE mode and the op-amp OP2 is in the OE mode, the power switches PSWH1 and PSWL1 may be turned on and the power switches PSWH2 and PSWL2 may be turned off; hence, the power sources of the driver circuit IC1 supply power to the op-amps OP1 and OP2. Therefore, the DC currents of power supply may flow to the op-amp OP2 through the power lines PL1 and PL2, and the AC currents accompanied by the output signal transmitted from the op-amp OP2 to the op-amp OP1 may also be supplied from the power sources of the driver circuit IC1. In such a situation, the EMI energies may still be canceled in a similar manner with the DC and AC current transmissions through the transmission interface.

Preferably, the signal pads of the driver circuits IC1 and IC2 may be deployed in an appropriate manner to optimize the EMI reduction effect. In an embodiment, the power pads for forwarding the power supply voltages VH and VL could be deployed at two opposite sides of the signal pad for forwarding the output signal VOUT. For example, as shown in FIG. 4, in the driver circuit IC1 or IC2, the power pad for forwarding the first power supply voltage VH is deployed at the upper side of the signal pad, and the power pad for forwarding the second power supply voltage VL is deployed at the lower side of the signal pad. Correspondingly, on the circuit board, the power line PL1 is deployed at the upper side of the signal line SL, and the power line PL2 is deployed at the lower side of the signal line SL; hence, the signal line SL is encompassed by the power lines PL1 and PL2. The EMI energies may further be suppressed if the signal line SL is encompassed by the power lines PL1 and PL2, thereby improving the performance of EMI reduction.

Note that the present invention aims at providing a signal transmission system with the common power loop to improve the EMI problem. Those skilled in the art may make modifications and alterations accordingly. For example, in the above embodiments, the signal transmission system is applied to realize signal transmissions between two ICs such as two DDICs used for a large-scale display panel or a splicing screen, where control signals or synchronization signals may be delivered between the DDICs to synchronize the display control. In another embodiment, the signals delivered between two ICs may be other types of signals, which should not be limited to those described in this disclosure. In another embodiment, the signal transmission system of the present invention may be applied to any types of circuits. As long as two devices or circuits communicate with each other by transmitting signals with current delivery, the common power scheme may be applicable to reduce the EMI problem. The EMI reduction technique with the common power scheme provided by the present invention is especially suitable for the display screen on a vehicle, but one of ordinary skills in the art would understand that it is applicable to any electronic devices having the EMI issue.

Also note that the common power scheme of the present invention may be combined with any other EMI reduction techniques to further improve the EMI problem. For example, in the above embodiment shown in FIG. 3, the common power scheme may be cooperated with slew rate control and/or swing range control to enhance the EMI performance. In another embodiment, other EMI reduction techniques, such as spread spectrum, may be implemented in the signal transmission system to further reduce the EMI energies.

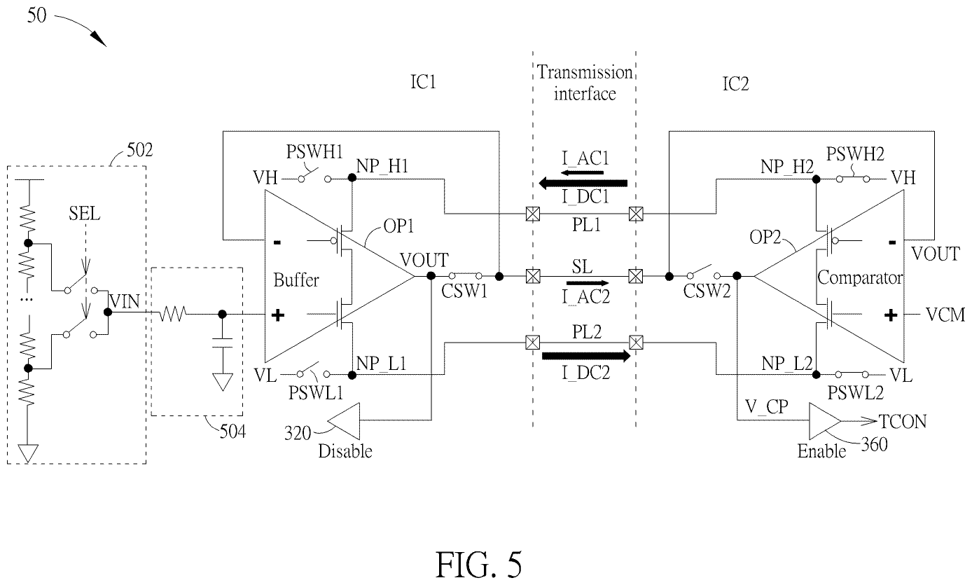

FIG. 5 is a schematic diagram of another signal transmission system 50 according to an embodiment of the present invention. The circuit structure of the signal transmission system 50 is similar to that of the signal transmission system 40, so signals and elements having similar functions are denoted by the same symbols. The difference between the signal transmission system 50 and the signal transmission system 40 is that, the signal transmission system 50 further includes a swing range control circuit 502 and a slew rate control circuit 504 in the driver circuit IC1.

As shown in FIG. 5, the swing range control circuit 502 includes a resistor string and several switches. By receiving a select signal SEL, the switches may be used to control the source signal VIN to swing on an appropriate voltage level, thereby determining the voltage level of the output signal VOUT, in order to suppress the emitted EMI energies. The select signal SEL may be received from a digital processing circuit such as the timing controller of the driver circuit IC1.

The slew rate control circuit 504 may be implemented with a low pass filter, where the values of the resistor and the capacitor may be well designed to control the slew rate of the source signal VIN, which thereby affects the slew rate of the output signal VOUT to be delivered through the transmission interface. With the well-controlled slew rate, the EMI energies emitted by the output signal VOUT may be suppressed. In other words, the high-frequency EMI could be suppressed by using the low pass filter contained in the slew rate control circuit 504.

In addition, the spread spectrum technique may also be applied to control the frequency of the output signal VOUT, so that the EMI energies emitted by the output signal VOUT may be suppressed. More specifically, the spread spectrum may control the frequency of the output signal VOUT to be tuned continuously within a range, thereby controlling the EMI energies to be dispersed over the spectrum and thus reducing the peak energies on the target frequency(s). In an embodiment, the spread spectrum may be applied to a signal source (not illustrated) for providing the source signal VIN, which may be included in a digital processing circuit such as the timing controller.

In one or several embodiments, the signal transmission system 50 is capable of bidirectional transmissions; hence, the driver circuit IC2 may also include similar implementations for realizing the swing range control circuit and/or the slew rate control circuit (not illustrated for brevity). The operations of these circuits are easily inferred by those skilled in the art, and thus are not narrated herein.

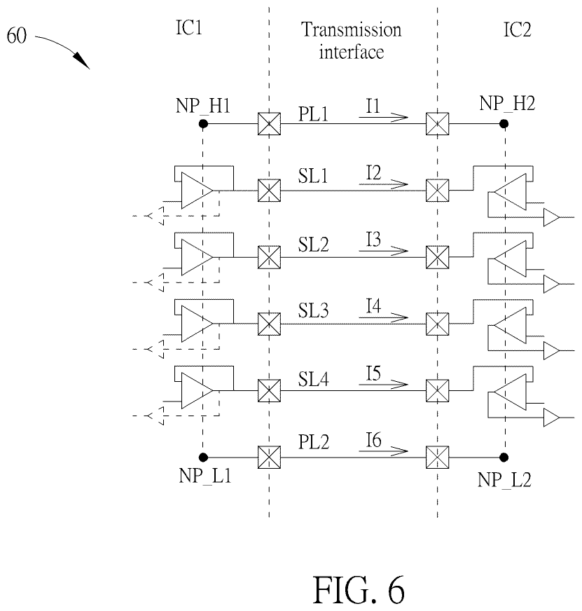

As mentioned above, the signal transmission system may include multiple signal lines connected between the two driver circuits. Therefore, the driver circuit at the transmitter side may apply a serial-to-parallel conversion to transmit the output signals through multiple channels, thereby increasing the throughput of the signal transmission system. FIG. 6 is a schematic diagram of a signal transmission system 60 in which the driver circuits IC1 and IC2 are connected through multiple signal lines SL1-SL4 and power lines PL1 and PL2, where the signals may be delivered through 4 channels corresponding to the 4 signal lines SL1-SL4. As shown in FIG. 6, each channel may have an op-amp in the driver circuit IC1 and an op-amp in the driver circuit IC2, and these op-amps are connected through one of the signal lines SL1-SL4. Assuming that the driver circuit IC1 is in the OE mode and the driver circuit IC2 is in the IE mode, each op-amp in the driver circuit IC1 may be operated as a unity gain buffer to transmit the output signals, and each op-amp in the driver circuit IC2 may be operated as a comparator to receive the output signals. The detailed operations of these op-amps are similar to those in the above embodiments, and will not be narrated herein.

As shown in FIG. 6, the op-amps in the driver circuit IC1 may be commonly coupled to a high-side power supply terminal NP H1 and a low-side power supply terminal NP_L1, to receive power from the power supply terminals NP H1 and NP_L1. The op-amps in the driver circuit IC2 may be commonly coupled to a high-side power supply terminal NP H2 and a low-side power supply terminal NP L2, to receive power from the power supply terminals NP H2 and NP L2. The high-side power supply terminal NP H1 in the driver circuit IC1 and the high-side power supply terminal NP H2 in the driver circuit IC2 are connected through the power line PL1. The low-side power supply terminal NP_L1 in the driver circuit IC1 and the low-side power supply terminal NP L2 in the driver circuit IC2 are connected through the power line PL2.

In such a situation, the 4 channels of the signal lines SL1-SL4 may commonly use the same power lines PL1 and PL2. If the driver circuit IC1 is in the OE mode and the driver circuit IC2 is in the IE mode, the power sources of the driver circuit IC2 may supply power to the op-amps in the driver circuits IC1 and IC2, where the power supply voltages from the driver circuit IC2 may be delivered to the driver circuit IC1 through the power lines PL1 and PL2. In another transmission mode, if the driver circuit IC1 is in the IE mode and the driver circuit IC2 is in the OE mode, the power sources of the driver circuit IC1 may supply power to the op-amps in the driver circuits IC1 and IC2, where the power supply voltages from the driver circuit IC1 may be delivered to the driver circuit IC2 through the power lines PL1 and PL2.

With the power and signal transmissions, the DC currents (e.g., I1 and I6) corresponding to the power supply may flow through the power lines PL1 and PL2, and the AC currents (e.g., I2-I5) corresponding to the output signals may flow through the signal lines SL1-SL4. Since these currents I1-I6 all originate from the same power source and sink to the same power source (i.e., the power source in the driver circuit IC2), the op-amps in the driver circuits IC1 and IC2 with the power lines PL1 and PL2 and the signal lines SL1-SL4 may form a closed current loop. Assuming that the rightward current transmission is represented by a positive current and the leftward current transmission is represented by a negative current, the summation of these currents I1-I6 may be equal to 0. In other words, the summation of all leftward currents is equal to the summation of all rightward currents. In such a situation, the EMI energies emitted by the leftward currents may be perfectly canceled by the EMI energies emitted by the rightward currents, thereby achieving a satisfactory EMI reduction performance.

Note that the rightward arrows of the currents I1-I6 shown in FIG. 6 are only used to specify that the rightward current transmission is a positive current. In this embodiment, since the driver circuit IC1 is in the OE mode and the driver circuit IC2 is in the IE mode, the current I1 flowing through the power line PL1 may be a leftward current (i.e., with a negative value), the current I6 flowing through the power line PL2 may be a rightward current (i.e., with a positive value), and the currents I2-I5 may be in any direction depending on the output signal values.

Preferably, in order to optimize the EMI reduction effect, the power pads and signal pads of the driver circuit IC1 or IC2 may be placed nearby, and the power lines PL1 and PL2 may be deployed to encompass the signal lines SL1-SL4, as shown in FIG. 6.

Note that FIG. 6 only shows the op-amps and corresponding A/D buffers in each of the driver circuits IC1 and IC2 to briefly describe the operations of the driver circuits IC1 and IC2. In the driver circuit IC1 operated as a signal transmitter in the OE mode, the A/D buffers may be disabled and the op-amps are connected as unity gain buffers. In the driver circuit IC2 operated as a signal receiver in the IE mode, the A/D buffers may be enabled and the op-amps are connected as comparators. Other necessary components such as power switches and control switches may be deployed in a similar way as those shown in FIG. 4, which are omitted in FIG. 6 for brevity without affecting the illustrations of the present embodiment.

As for a signal transmission system, the common power scheme provided in the present invention is superior to the conventional EMI reduction methods in various aspects. Table 1 shows the comparison between the common power scheme of the present invention and some general EMI reduction schemes, including the differential pair shown in FIG. 1 and the pseudo signal implementation shown in FIG. 2.

TABLE 1

| EMI reduction | Differential | Pseudo signal | Common power |
|---|---|---|---|
| scheme | pair | implementation | scheme |
| Bidirectional | No | Yes | Yes |
| transmission | | | |
| Pseudo signal & | No | Yes | No |
| current | | | |
| No. of pads/lines | 2N | 2N | N + 2 |

First, the common power scheme of the present invention is capable of bidirectional transmission. In comparison, the bidirectional transmission is feasible in the pseudo signal implementation, but not in the differential pair structure. However, the pseudo signal implementation requires an additional signal line for forwarding the pseudo signal and pseudo current. Therefore, if the signal transmission system has N channels, each driver circuit is requested to include 2N pads under the differential pair or the pseudo signal implementation, and there should be 2N transmission lines connected between the driver circuits. In comparison, the common power scheme of the present invention only needs N+2 pads and N+2 transmission lines to realize the signal transmissions of N channels, where N signal lines may be encompassed by 2 power lines to achieve the EMI reduction effect, as shown in FIG. 6. Note that N may be any positive integer; that is, the signal transmission system with the common power scheme may include any number of signal transmission channels, which is not limited to those described in this disclosure. As can be seen, the common power loop scheme may reduce the number of signal lines and pads approximately by half, and thus have more cost advantages when a greater number of channels are deployed.

To sum up, the present invention provides a signal transmission system with a common power loop to improve the EMI problem. The signal transmission system may include two driver circuits connected through two power lines and one or more signal lines. The op-amps in the driver circuits may receive power from the same power source from one of the driver circuits, thereby forming the common power loop; that is, a closed current loop is formed between the driver circuits through the op-amps, the power lines and the signal lines. The signal transmission system of the present invention is capable of bidirectional transmissions, where in a transmission mode, one driver circuit may be operated in the OE mode, and the other driver circuit may be operated in the IE mode. In such a situation, the op-amps may commonly receive power from the power source in the driver circuit operated in the IE mode (i.e., operated as a receiver). The common power scheme may achieve a satisfactory EMI reduction effect while the number of signal lines and pads may be reduced by half.

Those skilled in the art will readily observe that numerous modifications and alterations of the device and method may be made while retaining the teachings of the invention. Accordingly, the above disclosure should be construed as limited only by the metes and bounds of the appended claims.

1. A signal transmission system comprising:
a first operational amplifier, having a first power supply terminal and a second power supply terminal; and
a second operational amplifier, having a first power supply terminal and a second power supply terminal;
wherein the first operational amplifier and the second operational amplifier are connected through a plurality of transmission lines;
wherein the first power supply terminal of the first operational amplifier and the first power supply terminal of the second operational amplifier are connected through a first transmission line among the plurality of transmission lines, and the second power supply terminal of the first operational amplifier and the second power supply terminal of the second operational amplifier are connected through a second transmission line among the plurality of transmission lines.

2. The signal transmission system of claim 1, further comprising:
a first switch, coupled between the first power supply terminal of the first operational amplifier and a first power source;
a second switch, coupled between the second power supply terminal of the first operational amplifier and a second power source;
a third switch, coupled between the first power supply terminal of the second operational amplifier and a third power source; and
a fourth switch, coupled between the second power supply terminal of the second operational amplifier and a fourth power source.

3. The signal transmission system of claim 2, wherein the first switch and the second switch are turned off and the third switch and the fourth switch are turned on in a first transmission mode, and the first switch and the second switch are turned on and the third switch and the fourth switch are turned off in a second transmission mode.

4. The signal transmission system of claim 3, wherein the first operational amplifier is operated as a buffer and the second operational amplifier is operated as a comparator in the first transmission mode, and the first operational amplifier is operated as a comparator and the second operational amplifier is operated as a buffer in the second transmission mode.

5. The signal transmission system of claim 1, further comprising:
a fifth switch, coupled to an output terminal of the first operational amplifier; and
a sixth switch, coupled to an output terminal of the second operational amplifier;
wherein the fifth switch and the sixth switch are connected through a third transmission line among the plurality of transmission lines.

6. The signal transmission system of claim 5, wherein the fifth switch is turned on and the sixth switch is turned off in a first transmission mode, and the fifth switch is turned off and the sixth switch is turned on in a second transmission mode.

7. The signal transmission system of claim 1, wherein the first operational amplifier and the second operational amplifier receive power from a same power source.

8. The signal transmission system of claim 1, wherein a first power source of the second operational amplifier supplies a first power supply voltage to the first operational amplifier through the first transmission line, and a second power source of the second operational amplifier supplies a second power supply voltage to the first operational amplifier through the second transmission line.

9. The signal transmission system of claim 8, wherein the first operational amplifier transmits an output signal to the second operational amplifier by receiving the first power supply voltage and the second power supply voltage.

10. The signal transmission system of claim 1, wherein a current flows from a first power source of the second operational amplifier to a second power source of the second operational amplifier through the first transmission line, the first operational amplifier and the second transmission line.

11. The signal transmission system of claim 1, wherein the first operational amplifier, the second operational amplifier and the plurality of transmission lines form a closed current loop.

12. The signal transmission system of claim 1, wherein the first transmission line and the second transmission line are deployed to encompass other transmission lines among the plurality of transmission lines.

13. A signal transmission system comprising:
a first driver circuit, comprising a plurality of first operational amplifiers; and
a second driver circuit, comprising a plurality of second operational amplifiers;
wherein the first driver circuit and the second driver circuit are connected through a plurality of signal lines and a plurality of power lines;
wherein each of the plurality of first operational amplifiers is connected to a corresponding second operational amplifier among the plurality of second operational amplifiers through one of the plurality of signal lines;
wherein the plurality of first operational amplifiers are commonly coupled to a first power supply terminal and a second power supply terminal in the first driver circuit, and the plurality of second operational amplifiers are commonly coupled to a third power supply terminal and a fourth power supply terminal in the second driver circuit;
wherein the first power supply terminal and the third power supply terminal are connected through a first power line among the plurality of power lines, and the second power supply terminal and the fourth power supply terminal are connected through a second power line among the plurality of power lines.

14. The signal transmission system of claim 13, wherein the first driver circuit further comprises:
a first switch, coupled between the first power supply terminal and a first power source; and
a second switch, coupled between the second power supply terminal and a second power source; and
the second driver circuit further comprises:
a third switch, coupled between the third power supply terminal and a third power source; and
a fourth switch, coupled between the fourth power supply terminal and a fourth power source.

15. The signal transmission system of claim 14, wherein the first switch and the second switch are turned off and the third switch and the fourth switch are turned on in a first transmission mode, and the first switch and the second switch are turned on and the third switch and the fourth switch are turned off in a second transmission mode.

16. The signal transmission system of claim 15, wherein each of the plurality of first operational amplifiers is operated as a buffer and each of the plurality of second operational amplifiers is operated as a comparator in the first transmission mode, and each of the plurality of first operational amplifiers is operated as a comparator and each of the plurality of second operational amplifiers is operated as a buffer in the second transmission mode.

17. The signal transmission system of claim 13, wherein the first driver circuit further comprises:
a plurality of fifth switches, each coupled to an output terminal of one of the plurality of first operational amplifiers; and
the second driver circuit further comprises:
a plurality of sixth switches, each coupled to an output terminal of one of the plurality of second operational amplifiers;
wherein each of the plurality of fifth switches is connected to a corresponding sixth switch among the plurality of sixth switches through one of the plurality of signal lines.

18. The signal transmission system of claim 17, wherein each of the plurality of fifth switches is turned on and each of the plurality of sixth switches is turned off in a first transmission mode, and each of the plurality of fifth switches is turned off and each of the plurality of sixth switches is turned on in a second transmission mode.

19. The signal transmission system of claim 13, wherein the plurality of first operational amplifiers and the plurality of second operational amplifiers receive power from a same power source.

20. The signal transmission system of claim 13, wherein a first power source of the plurality of second operational amplifiers supplies a first power supply voltage to the plurality of first operational amplifiers through the first power line, and a second power source of the plurality of second operational amplifiers supplies a second power supply voltage to the plurality of first operational amplifiers through the second power line.

21. The signal transmission system of claim 20, wherein one of the plurality of first operational amplifiers transmits an output signal to the corresponding second operational amplifier among the plurality of second operational amplifiers by receiving the first power supply voltage and the second power supply voltage.

22. The signal transmission system of claim 13, wherein a current flows from a first power source of the second operational amplifier to a second power source of the second operational amplifier through the first power line, at least one of the plurality of first operational amplifiers, and the second power line.

23. The signal transmission system of claim 13, wherein at least one of the plurality of first operational amplifiers, at least one of the plurality of second operational amplifiers, the plurality of signal lines and the plurality of power lines form a closed current loop.

24. The signal transmission system of claim 13, wherein the first power line and the second power line are deployed to encompass the plurality of signal lines.

25. A signal transmission system comprising:
a first driver circuit, comprising:
a first amplifier circuit; and
a first power control circuit, having a first power source and at least one first power switch; and
a second driver circuit, comprising:
a second amplifier circuit; and
a second power control circuit, having a second power source and at least one second power switch;
wherein the first driver circuit and the second driver circuit are connected through a plurality of transmission lines;
wherein the first amplifier circuit and the second amplifier circuit are connected through at least one signal line among the plurality of transmission lines;
wherein the first power control circuit and the second power control circuit are connected through a plurality of power lines among the plurality of transmission lines.

26. The signal transmission system of claim 25, wherein in a first transmission mode, the at least one first power switch is turned off and the at least one second power switch is turned on to control the first amplifier circuit and the second amplifier circuit to receive power from the second power source, and in a second transmission mode, the at least one first power switch is turned on and the at least one second power switch is turned off to control the first amplifier circuit and the second amplifier circuit to receive power from the first power source.

27. The signal transmission system of claim 26, wherein in the first transmission mode, the first amplifier circuit receives power from the second power source through the plurality of power lines, and in the second transmission mode, the second amplifier circuit receives power from the first power source through the plurality of power lines.

28. A first driver circuit comprising:
an operational amplifier, to be coupled to a second driver circuit through a plurality of transmission lines;
a first switch, coupled between a first power supply terminal of the operational amplifier and a first power source; and
a second switch, coupled between a second power supply terminal of the operational amplifier and a second power source.

29. The first driver circuit of claim 28, wherein the first power supply terminal is connected to the second driver circuit through a first power line among the plurality of transmission lines, and the second power supply terminal is connected to the second driver circuit through a second power line among the plurality of transmission lines.

30. The first driver circuit of claim 29, wherein the operational amplifier transmits an output signal to the second driver circuit by receiving a power supply voltage from the second driver circuit through at least one of the first power line and the second power line.

31. The first driver circuit of claim 28, wherein the first switch and the second switch are turned off in a first transmission mode, and turned on in a second transmission mode.

32. The first driver circuit of claim 31, wherein the operational amplifier is operated as a buffer in the first transmission mode, and operated as a comparator in the second transmission mode.

33. The first driver circuit of claim 28, further comprising:
a third switch to couple an output terminal of the operational amplifier to the second driver circuit through a signal line among the plurality of transmission lines.
